(19) United States
(12) Patent Application Publication
(10) Pub. No.: US 2014/0360670 A1
(43) Pub. Date: Dec. 11, 2014

(54) PROCESSING SYSTEM FOR NON-AMBIPOLAR ELECTRON PLASMA (NEP) TREATMENT OF A SUBSTRATE WITH SHEATH POTENTIAL

(71) Applicant: Tokyo Electron Limited, Tokyo (JP)

(72) Inventors: Lee Chen, Cedar Creek, TX (US); Merritt Funk, Austin, TX (US); Zhiying Chen, Austin, TX (US)

(73) Assignee: TOKYO ELECTRON LIMITED, Tokyo (JP)

(21) Appl. No.: 14/026,092

(22) Filed: Sep. 13, 2013

Related U.S. Application Data
(60) Provisional application No. 61/831,401, filed on Jun. 5, 2013.

(51) Int. Cl. H01J 37/32

(52) U.S. Cl. CPC H01J 37/32357
USPC 156/345.29

(57) ABSTRACT

A processing system is disclosed, having a plasma source chamber that excites source plasma to generate an electron beam, and a process chamber that houses a substrate for exposure of the substrate to the electron beam. The processing system also includes an electron injector that injects electrons from the source plasma into the electron beam as the electron beam enters the process chamber. The electron beam includes a substantially equal number of electrons and positively charged ions in the process chamber. In one embodiment, the processing system also includes a magnetic field generator that generates a magnetic field in the process chamber to capture the electrons included in the electron beam to generate a voltage potential between the magnetic field generator and the substrate. The voltage potential accelerates the positively charged ions to the substrate and minimizes the electrons that reach the substrate.

### CROSS REFERENCE TO RELATED APPLICATION

Pursuant to 37 C.F.R. §1.78(a)(4), this application claims the benefit of and priority to prior filed co-pending Provisional Application Ser. No. 61/831,401 filed Jun. 5, 2013, which is expressly incorporated herein by reference.

### FIELD OF THE INVENTION

This invention relates to semiconductor processing technology, and more particularly, to apparatus and methods for controlling properties of a processing system for treating a substrate.

### BACKGROUND OF THE INVENTION

Typically, plasma is used in semiconductor processing to assist etch processes by facilitating the removal of material along fine lines or within vias patterned on a substrate. Conventional etch processes that use plasma include capacitively or inductively coupled plasma, hallow cathode plasma, electron cyclotron resonance plasma, microwave surface wave plasma, and reactive ion etching (RIE). For example, RIE generates plasma via electromagnetic fields with high-energy ions to etch away unwanted materials of the substrate.

High-energy ions generated in RIE are difficult to control within the plasma. As a result, conventional RIE techniques are accompanied with several issues that hinder the overall performance in etching the substrate due to the lack of control of the high-energy ions. Conventional RIE techniques often have broad ion energy distribution (IED) that results in a broad ion beam used to etch the substrate. A broad ion beam decreases the precision required to adequately etch the substrate. Conventional RIE techniques are also accompanied with several charge-induced side effects such as charge damage to the substrate. Conventional RIE techniques are also accompanied with feature-shape loading effects such as micro loading. Micro loading results when an etching rate of the RIE increases due to a dense area of the substrate. The increased etching rate may result in damage to the substrate.

It is becoming common wisdom to use conventional electron beam excited plasma to process substrates. Conventional electron beam excited plasma processes generate an electron beam that is used to treat the substrate. The addition of electrons to the positively charged ions forming the electron beam provides better control over the positively charged ions, which improves electron and ion energy distributions at the substrate as compared to other conventional plasma processes.

Conventional electron beam excited plasma processes generate the electron beam by exciting plasma and then injecting the electron beam into a processing chamber to treat the substrate housed in the processing chamber. A magnetic field is typically applied to plasma housed in a chamber independent of the processing chamber to excite the electrical characteristics of the plasma that then generates the electron beam. The positively charged ions of the electron beam are then accelerated through a series of differentially biased grids so that the positively charged ions of the electron beam reach the substrate.

Positively charged ions of the electron beam generated by conventional electron beam excited processes often times lose their ionization characteristics as the positively charged ions are accelerated through each of the differentially biased grids limiting the amount of positively charged ions that reach the substrate in the processing chamber, thus limiting the ionization efficiency of the electron beam. The lack of control over ionization efficiency of the electron beam limits the ability to obtain desirable levels of ion energy distribution to adequately treat the substrate. Therefore, an effective means to maintain ionization efficiency in the electron beam by minimizing the differentially biased grids that the electron beam passes through is needed.

### SUMMARY OF THE INVENTION

The present invention provides a processing system for non-ambipolar electron plasma (NEP) treatment of a substrate, including a plasma source chamber configured to excite source plasma to generate an electron beam, and a process chamber configured to house a substrate for exposure of the substrate to the electron beam. The processing system also includes an electron injector configured to inject electrons from the source plasma into the electron beam as the electron beam enters the process chamber. The electron beam includes a substantially equal number of electrons and positively charged ions in the process chamber. The processing system also includes a magnetic field generator configured to generate a voltage potential between the magnetic field generator and the substrate. The voltage potential accelerates the positively charged ions to the substrate and minimizes the electrons that reach the substrate.

The present invention also provides a processing system for NEP treatment of a substrate, including a plasma source chamber configured to excite source plasma to generate an electron beam, and a process chamber configured to house a substrate for exposure of the substrate to the electron beam. The processing system also includes an electron injector configured to inject electrons from the source plasma into the electron beam as the electron beam enters the process chamber. The electron beam includes a substantially equal number of electrons and positively charged ions in the process chamber. The processing system also includes a positively charged ion accelerator configured to generate a direct current (DC) voltage to the process chamber to accelerate the positively charged ions to the substrate and minimize the electrons that reach the substrate.

The present invention also provides for NEP treatment of a substrate, including a plasma source chamber configured to excite source plasma to generate an electron beam, and a process chamber configured to house a substrate for exposure of the substrate to the electron beam. The processing system also includes an electron injector configured to inject electrons from the source plasma into the electron beam as the electron beam enters the process chamber. The electron beam includes a substantially equal number of electrons and positively charged ions in the process chamber. The processing system also includes a magnetic field generator configured to capture the electrons included in the electron beam to generate a sheath potential between the substrate and the magnetic field generator from a magnetic field generated by the magnetic field generator. The sheath potential attracts the positively charged ions to the substrate and minimizes the electrons that reach the substrate. The processing system also includes a positively charged ion accelerator configured to generate an accelerator voltage to the process chamber to accelerate the positively charged ions to the substrate.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention. Additionally, the left most digit(s) of a reference number identifies the drawing in which the reference number first appears.

FIG. 1 is a schematic cross-sectional illustration of an exemplary processing system for neutral beam treatment of a substrate in accordance with an embodiment of the disclosure;

FIG. 2 is a schematic cross-sectional illustration of an exemplary processing system for neutral beam treatment of a substrate in accordance with an embodiment of the disclosure;

FIG. 3 is a schematic cross-sectional illustration of an exemplary processing system for neutral beam treatment of a substrate in accordance with an embodiment of the disclosure;

FIG. 4 is a schematic cross-sectional illustration of an exemplary processing system for neutral beam treatment of a substrate in accordance with an embodiment of the disclosure;

FIG. 5 is a flowchart of exemplary operational steps of a processing system according to an exemplary embodiment of the present disclosure;

FIG. 6 is a schematic cross-sectional illustration of an exemplary processing system for non-ambipolar electron plasma (NEP) treatment of a substrate in accordance with an embodiment of the disclosure; and

FIG. 7 is a schematic cross-sectional illustration of an exemplary processing system for NEP treatment of a substrate in accordance with an embodiment of the disclosure.

The present disclosure will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION

The following Detailed Description refers to accompanying drawings to illustrate exemplary embodiments consistent with the present disclosure. References in the Detailed Description to “one exemplary embodiment,” “an exemplary embodiment,” “an example exemplary embodiment,” etc., indicate that the exemplary embodiment described can include a particular feature, structure, or characteristic, but every exemplary embodiment does not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to affect such feature, structure, or characteristic in connection with other exemplary embodiments whether or not explicitly described.

The exemplary embodiments described herein are provided for illustrative purposes, and are not limiting. Other exemplary embodiments are possible, and modifications can be made to exemplary embodiments within the scope of the present disclosure. Therefore, the Detailed Description is not meant to limit the present disclosure. Rather, the scope of the present disclosure is defined only in accordance with the following claims and their equivalents.

The following Detailed Description of the exemplary embodiments will so fully reveal the general nature of the present disclosure that others can, by applying knowledge of those skilled in the relevant art(s), readily modify and/or adapt for various applications such exemplary embodiments, without undue experimentation, without departing from the scope of the present disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not limitation, such that the terminology or phraseology of the present specification is to be interpreted by those skilled in the relevant art(s) in light of the teachings herein.

For more efficient electron beam treatment of a substrate the present invention provides a non-ambipolar electron plasma (NEP) system. The NEP system generates an electron beam that is a neutral beam in that the positively charged ions included in the neutral beam are balanced by negatively charged electrons. The NEP system includes a plasma generation chamber that generates source plasma and a process chamber that includes electron beam excited plasma and also the substrate that is to be treated. The source plasma may be excited by a magnetic field that generates electron flux within the source plasma. The electron flux passes from the source plasma located in the plasma generation chamber into the process chamber to generate the electron beam excited plasma that treats the substrate. For ease of discussion, the electron flux generated by the excitation of the electron beam plasma by the magnetic field will simply be referred to as the electron beam.

One of ordinary skill in the art will recognize that the travelling of the electron beam from the plasma generation chamber to the process chamber occurs based on a difference in electric potential between the source plasma and the electron beam excited plasma. The electric potential of the electron beam excited plasma is elevated relative to the electric potential of the source plasma. Consequently, the electron flux included in the electron beam moves from the plasma generation chamber to the process chamber to treat the substrate.

For example, the ion efficiency of the electron beam increases in the NEP system as compared to conventional electron beam excited processes. The plasma generation chamber and the process chamber in the NEP system are separated by a single dielectric electron injector. As the plasma housed in the plasma generation chamber is excited forming the electron beam, the high-energy electrons included in the plasma housed in the plasma generation chamber flow through the single dielectric electron injector into the processing chamber. The single dielectric electron injector injects negatively charged electrons into the electron beam injected into the processing chamber balancing the positively charged ions also included in the electron beam. The injection of the negatively charged electrons into the electron beam maintains the ionization of the positively charged ions as the electron beam flows through the process chamber so that the positively charged ions do not lose their positive charge as the electron beam travels towards the substrate, thus improving the ionization efficiency of the electron beam.

Although the negatively charged electrons included in the electron beam are necessary so that the positively charged ions do not lose their positive charge as the electron beam travels towards the substrate, the quantity of negatively charged electrons that actually reach the substrate is to be minimized. The negatively charged electrons may damage the substrate. As a result, the process chamber in the NEP system includes a magnetic field generator and/or a positively charged ion accelerator that generates voltage potential between the generator and/or accelerator and the substrate. The voltage potential slows the negatively charged electrons included in the electron beam so that the quantity of negatively charged electrons that reach the substrate is minimized while accelerating the positively charged ions towards the substrate so that the quantity of positively charged ions that reach the substrate to treat the substrate is maximized.

Conventional electron beam excited processes use a series of differentially biased grids to accelerate the positively charged ions of the electron beam to the process chamber to treat the substrate. The positively charged ions have a greater likelihood of losing their positive charge as they pass through each differentially biased grid, thus worsening the ion efficiency of the electron beam. Thus, the ion efficiency of the electron beam that passes through the differentially charged biased grids as used in conventional electron beam excited processes is less than the single dielectric electron injector used by the NEP system.

As the following description will show in detail, the disclosed invention takes advantage of this property to increase the ion efficiency of positively charged ions that treat the substrate while limiting the quantity of negatively charged electrons that reach the substrate. This serves to improve the efficiency and effectiveness in treating the substrate via the electron beam while minimizing potential damage to the substrate that may be caused by the negatively charged ions. In the description that follows, even though references may be made to NEP, it should be understood that the system and method apply to a variety of desired electron beams (electron beams of chosen charge characteristics).

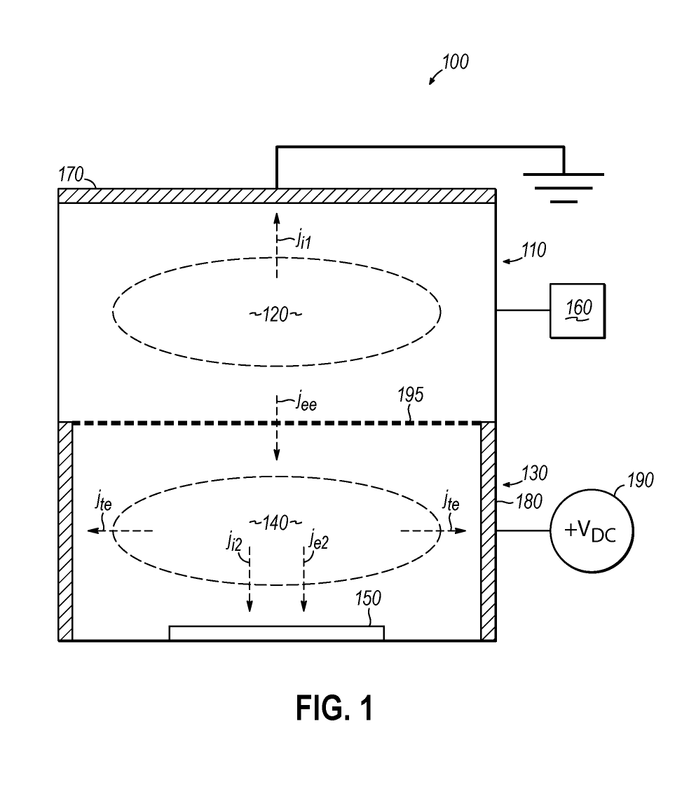

FIG. 1 depicts a processing system 100 for neutral beam treatment of a substrate. The processing system 100 includes a plasma generation chamber 110 that forms a source plasma 120 at a source plasma potential (Vₚ, 1) and a process chamber 130 that forms an electron beam excited plasma 140 at an electron beam excited plasma potential (Vₚ, 2). The electron beam excited plasma potential is greater than the source plasma potential (Vₚ, 2>Vₚ, 1).

A coupling power, such as radio frequency (RF) power for example, may be applied to the source plasma 120 to form an ionized gas. The electron beam excited plasma 140 may be formed using electron flux generated by the source plasma 120. The electron flux may include but is not limited to energetic electron (ee) flux, current (jₑₑ) flux and/or any other type of flux generated by the source plasma 120 that may be used to form the electron beam excited plasma 140 that will be apparent to those skilled in the relevant art(s) without departing from the scope of the present disclosure. The processing system 100 also includes a substrate holder (not shown) that may position a substrate 150. The substrate 150 may be positioned at a direct current (DC) ground or a floating ground in the process chamber 130 so that the substrate 150 may be exposed to the electron beam excited plasma 140 at the electron beam excited plasma potential.

The plasma generation chamber 110 may be coupled to a plasma generation system 160. The plasma generation system 160 may ignite and heat the source plasma 120. The plasma generation system 160 may heat the source plasma 120 so that a minimum fluctuation in the source plasma potential is achieved. The plasma generation system 160 may include but is not limited to an inductively coupled plasma (ICP) source, a transformer coupled plasma (TCP) source, a capacitively coupled plasma (CCP) source, an electron cyclotron resonance (ECR) source, a helicon wave source, a surface wave plasma source, a surface wave plasma source having a slotted plane antenna, and/or any other plasma generating system that may heat the source plasma 120 with minimum fluctuation in the source plasma potential that will be apparent to those skilled in the relevant art(s) without departing from the scope of the present disclosure.

The plasma generation chamber 110 is also coupled to a direct current (DC) conductive electrode 170. The DC conductive electrode 170 includes a conductive surface that may be in contact with the source plasma 120. The DC conductive electrode 170 may be coupled to DC ground, and may act as an ion sink that may be driven by the source plasma 120 at the source plasma potential. The source plasma chamber 110 may be coupled to any quantity of DC conductive electrodes 170 coupled to DC ground that will be apparent to those skilled in the relevant art(s) without departing from the scope of the present disclosure.

The DC conductive electrode 170 may affect the source plasma potential, and may provide the lowest impedance path to DC ground. The source plasma potential may be lowered when the surface area of the conductive surface of the DC conductive electrode 170 in contact with the source plasma 120 is greater than the surface areas of other surfaces also in contact with the source plasma 120. The greater the surface area of the conductive surface in contact with the source plasma 120 relative to the surface areas of other surfaces also in contact with the source plasma 120 provides a greater discrepancy in the impedance of the conductive surface relative to the impedances of the other surfaces, and this greater discrepancy provides a lower impedance path to DC ground for the source plasma 120 and thus lowers the source plasma potential.

The electron current jₑₑ may be electron flux from the source plasma 120 that may initiate and/or sustain the electron beam excited plasma 140 in the process chamber 130. The electron current jₑₑ may be controlled to produce a neutral beam. In order to generate the neutral beam, the source plasma potential and the electron beam excited plasma potential are stabilized with minimal fluctuations between each. To maintain the stability of the electron beam excited plasma 140, the process chamber 130 includes a DC conductive bias electrode 180 having a conductive surface in contact with the electron beam excited plasma 140.

The DC conductive bias electrode 180 may be coupled to a DC voltage source 190. The DC voltage source 190 may bias the DC conductive bias electrode 180 at a positive DC voltage (+V_{DC}). As a result, the electron beam excited plasma potential may be a boundary-driven plasma potential driven by the positive DC voltage source, thus causing the electron beam excited plasma potential (Vₚ, 2) to rise substantially to the positive DC voltage (+V_{DC}) and remain substantially stable at the positive DC voltage (+V_{DC}). The process chamber 130 may be coupled to any quantity of DC conductive electrodes 180 coupled to the DC voltage source 190 that will be apparent to those skilled in the relevant art(s) without departing from the scope of the present disclosure.

The processing system also includes a separation member 195 disposed between the plasma generation chamber 110 and the process chamber 130. The separation member 195 may act as an electron diffuser. The separation member 195 may be driven by an electric field through an electron acceleration layer created by a voltage potential difference of (Vₚ, 2)-(Vₚ, 1). The separation member 195 may include an insulator, quartz, alumina, a dielectric coated conductive material that is electrically floating with high RF impedance to ground, and/or any other separation member 195 that will be apparent to those skilled in the relevant art(s) without departing from the scope of the present disclosure. Due to the large electric field sustained across the separation member 195 of (Vₚ, 2)-(Vₚ, 1), the electron current jₑₑ is sufficiently energetic to sustain ionization in the electron beam excited plasma 140.

The separation member 195 may include one or more openings to permit the passage of electron current jₑₑ from the plasma generation chamber 110 to the process chamber 130. The total area of the one or more openings may be adjusted relative to the surface area of the DC conductive electrode 170 to ensure a relatively large potential difference of (Vₚ, 2)-(Vₚ, 1) while minimizing reverse ion current from the electron beam excited plasma 140 to the source plasma 120 thereby ensuring a sufficient ion energy jᵢ₂ and jₑ₂ for ions striking the substrate 150.

Ion current jᵢ₁ may be a first ion flux from a first population of ions in the source plasma 120 that flows in the source plasma chamber 110 to the DC conductive electrode 170 in a quantity approximately equivalent to the electron current jₑₑ. The electron current jₑₑ may flow from the source plasma 120 through the electron acceleration layer (not shown) at the separation member 195 into the electron beam excited plasma 140. The electron current jₑₑ may be sufficiently energetic to form the electron beam excited plasma 140. In doing so, a population of thermal electrons and a second population of ions are formed. The thermal electrons may be the result of electrons ejected upon ionization of the electron beam excited plasma 140 by the incoming electron current jₑₑ. Some energetic electrons from the electron current jₑₑ may lose a sufficient amount of energy and also become part of the thermal electron population.

Due to Debye shielding, the thermal electrons of the electron beam excited plasma 140 may flow to the DC conductive bias electrode 180 as the thermal electron current jₜₑ in a quantity substantially equal to the energetic electron flux of jₜₑ-jₑₑ. With the thermal electrons directed to the DC conductive bias electrode 180, a second ion flux from the second population of ions in ion current jᵢ₂ may be directed to the substrate 150 at the second voltage potential. A substantial amount of ion current jᵢ₂ may survive passage through the electron beam excited plasma 140 and strike the substrate 150 when the incoming energetic electron energy in electron current jₑₑ is high. Because the substrate 150 may be at a floating DC ground, the ion current jᵢ₂ that may be fed by the second ion population in the electron beam excited plasma 140 may be substantially equivalent to the electron current jₑ₂ so that there is no net current.

As a result, the elevation of the electron beam excited plasma potential above the source plasma potential may drive an energetic electron beam having electron current jₑₑ to form the electron beam excited plasma 140. The particle balance throughout the processing system 100 may provide the energetic electron beam with an equal number of electrons with electron current jₑ₂ and ions with ion current jₑ₂ striking the substrate 150 so that the energetic electron beam is a neutral beam where the electron current jₑ₂ is substantially equal to the ion current jᵢ₂. The charge balance of the neutral beam directed at the substrate 150 activates a chemical process at the substrate 150.

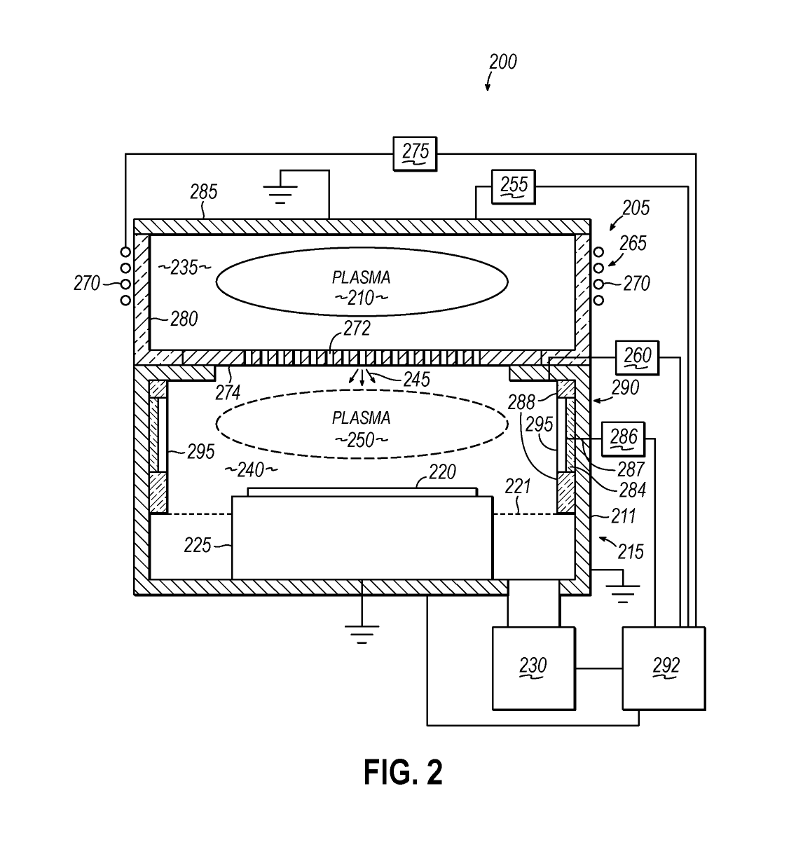

Referring to FIG. 2, in which like reference numerals are used to refer to like parts, a processing system 200 for neutral beam treatment of a substrate is shown. The processing system 200 shares many similar features with the processing system 100; therefore, only the differences between the processing system 200 and the processing system 100 are to be discussed in further detail. The processing system 200 includes a plasma generation chamber 205 that produces source plasma 210 at source plasma potential (Vₚ, 1). The processing system 200 also includes a process chamber 215 that provides a contaminant-free, vacuum environment for plasma processing of a substrate 220. The process chamber 215 includes a substrate holder 225 that supports substrate 220. The process chamber 215 is coupled to a vacuum pumping system 230 to evacuate the process chamber 215 and control a pressure in the process chamber 215.

The plasma generation chamber 205 includes a source plasma region 235 that receives a first process gas at a first pressure to form the source plasma 210. The process chamber 215 includes an electron beam excited plasma region 240 disposed downstream of the source plasma region 235 to receive electron flux 245 and a first process gas from the source plasma region 235 to form an electron beam excited plasma 250 at an electron beam excited plasma potential (Vₚ, 2) and a second pressure.

A first gas injection system 255 is coupled to the plasma generation chamber 205 to introduce the first process gas to the source plasma region 235. The first process gas may include an electropositive gas, an electronegative gas, or a mixture thereof. For example, the first process gas may include a noble gas, such as argon (Ar), and/or any other gas suitable for treating substrate 220 that will be apparent to those skilled in the relevant art(s) without departing from the scope of the present disclosure. Further, the first process gas may include chemical constituents such as etchants, film forming gases, dilutants, cleaning gases and/or any other chemical constituent suitable for treating substrate 220 that will be apparent to those skilled in the relevant art(s) without departing from the scope of the present disclosure.

An optional second gas injection system 260 may be coupled to the process chamber 215 to introduce a second process gas to the electron beam excited plasma region 240. The second process gas includes any gas suitable for treating substrate 220. The second process gas may include an electropositive gas, an electronegative gas, or a mixture thereof. For example, the second process gas may include a noble gas, such as argon (Ar), and/or any other gas suitable for treating substrate 220 that will be apparent to those skilled in the relevant art(s) without departing from the scope of the present disclosure. Further, the second process gas may include chemical constituents such as etchants, film forming gases, dilutants, cleaning gases and/or any other chemical constituent suitable for treating substrate 220 that will be apparent to those skilled in the relevant art(s) without departing from the scope of the present disclosure.

The processing system 200 includes a plasma generation system 265 coupled to the plasma generation chamber 205 to generate the source plasma 210 in the source plasma region 235. The plasma generation system 265 may produce a capacitively coupled plasma (CCP), an inductively coupled plasma (ICP), a transformer coupled plasma (TCP), a surface wave plasma, a helicon wave plasma, an electron cyclotron resonant (ECR) heated plasma, and/or any other type of plasma that will be apparent to those skilled in the relevant art(s) without departing from the scope of the present disclosure. The source plasma 210 may be heated to produce a minimum fluctuation in the source plasma potential (Vₚ, 1).

The plasma generation system 265 may include an inductive coil 270 that may be coupled to a power source 275. The power source 275 may include a RF generator that couples RF power through an impedance match network to the inductive coil 270. RF power may be inductively coupled from the inductive coil 270 through a dielectric window 280 to the source plasma 210 in the source plasma region 235. The frequency of the RF power generated by the inductive coil 270 may range from 10 MHz to 100 MHz. A slotted Faraday shield (not shown) may be employed to reduce capacitive coupling between the inductive coil 270 and the source plasma 210.

An impedance match network may improve the transfer of RF power to plasma by reducing the reflected power. Match network topologies include but are not limited to L-type, N-type, T-type and/or any other match network topology that will be apparent to those skilled in the relevant art(s) without departing from the scope of the present disclosure. In an electropositive discharge of the source plasma 210, the electron density may range from approximately 10¹⁰ cm³ to 10¹³ cm³, and the electron temperature may range from 1 eV to about 10 eV depending on the type of plasma source that is used.

Additionally, the plasma generation chamber 205 includes a DC conductive electrode 285. The DC conductive electrode 285 includes a conductive surface that acts as a boundary that is in contact with the source plasma 210. The DC conductive electrode 285 may be coupled to DC ground. The DC conductive ground electrode 285 may include a doped silicon electrode. The DC conductive ground electrode 285 may act as an ion sink that is driven by the source plasma 210 at the source plasma potential (Vₚ, 1).

The processing system 200 also includes a bias electrode system 290 that is coupled to the process chamber 215. The bias electrode system 290 may elevate the electron beam excited plasma potential (Vₚ, 2) to a value above the source plasma potential (Vₚ, 1) in order to drive the electron flux 245. The bias electrode system 290 includes a DC conductive bias electrode 295 having a conductive surface in contact with the electron beam excited plasma 250. The DC conductive bias electrode 295 may be electrically insulated from the process chamber 215 via insulator 284. The DC conductive bias electrode 295 may be coupled to a DC voltage source 286. The DC conductive bias electrode 295 may include a conductive material, such as metal and/or doped silicon.

The DC conductive bias electrode 295 may include a relatively large area in contact with the electron beam excited plasma 250. The larger the area at +V_{DC}, the closer the electron beam excited plasma potential (Vₚ, 2) will be to +V_{DC}. As an example, the total area of the DC conductive bias electrode 295 may be greater than the total sum of all other conductive surfaces that are in contact with the electron beam excited plasma 250. Alternatively, the total area of the DC conductive bias electrode 295 may be the only conductive surface that is in contact with the electron beam excited plasma 250.

The voltage source 286 may include a variable DC power supply. Additionally, the voltage source 286 may include a bipolar DC power supply. The voltage source 286 may include means to monitor, adjust, and/or control the polarity, current, voltage, and/or the on/off state of the voltage source 286. An electrical filter may de-couple the RF power from the voltage source 286. For example, the DC voltage applied to the DC conductive bias electrode 295 by the voltage source 286 may range from approximately 0 volts (V) to approximately 10,000V. Desirably, the DC voltage applied to the DC conductive bias electrode 295 by DC voltage source 286 may range from approximately 50V to approximately 5000V. The DC voltage may be a positive voltage having an absolute value greater than approximately 50V.

The process chamber 215 includes a chamber housing member 211 that may be coupled to ground. A liner member 288 may be disposed between the chamber housing member 211 and the electron beam excited plasma 250. The liner member 288 may be fabricated from a dielectric material, such as quartz and/or alumina for example. The liner member 288 may provide a high RF impedance to ground for the electron beam excited plasma 250. An electrical feed-through 287 may allow an electrical connection to the DC conductive bias electrode 295.

A separation member 274 may be disposed between the source plasma region 235 and the electron beam excited plasma region 240. The separation member 274 may include one or more openings 272 to allow passage of the first process gas as well as electron flux 245 from the source plasma 210 in the source plasma region 235 to the electron beam excited plasma region 240 in order to form the electron beam excited plasma 250 in the electron beam excited plasma region 240. The one or more openings 272 in the separation member 274 may include super-Debye length apertures where the transverse dimension or diameter may be larger than the Debye length. The one or more openings 272 may be sized to permit adequate electron transport while allowing a sufficiently high potential difference between the source plasma potential (Vₚ, 1) and the electron beam excited plasma potential (Vₚ, 2) to reduce reverse ion current between the electron beam excited plasma 250 and the source plasma 210. The one or more openings 272 may also be sized to sustain a pressure difference between a first pressure in the source plasma region 235 and a second pressure in the electron beam excited plasma region 240.

The electron flux 245 may be generated between the source plasma region 235 and the electron beam excited plasma region 240 through the separation member 274. The electron flux 245 is driven by electric field diffusion where the electric flux 245 is established by the potential difference between the source plasma potential (Vₚ, 1) and the electron beam excited plasma potential (Vₚ, 2). The electron flux 245 may be sufficiently energetic to sustain ionization in the electron beam excited plasma 250.

The vacuum pumping system 230 may include a turbo-molecular vacuum pump (TMP) capable of pumping speed up to 5000 liters per second and a vacuum valve, such as a gate valve, for controlling the pressure in the electron beam excited plasma region 250. A pressure measuring device for monitoring chamber pressure (not shown) may be coupled to the process chamber 215.

The substrate holder 225 may be coupled to ground. The substrate 220 may be at a floating ground when the substrate holder 225 is coupled to ground. As a result, the only ground that the electron beam excited plasma 250 is in contact with is the floating ground provided by the substrate 220. The substrate 220 may be clamped to the substrate holder 225 via a ceramic electrostatic clamp (ESC) layer. The ESC layer may insulate the substrate 220 from the ground substrate holder 225. The processing system 100 may also include a substrate bias system coupled to the substrate holder 225 to electrically bias the substrate 220. For example, the substrate holder 225 may include an electrode that is coupled to a RF generator through an impedance match network. A frequency for the power applied to the substrate holder 225 may range from 0.1 MHz to 100 MHz.

The processing system 200 may include a substrate temperature control system (not shown) coupled to the substrate holder 225 to adjust the temperature of the substrate 220. The substrate temperature control system includes temperature control elements. The temperature control elements may include a cooling system to re-circulate coolant flow after receiving heat from the substrate holder 225 and transfer the heat to a heat exchanger system. The temperature control elements may also transfer heat from the heat exchanger system when heating the substrate holder 225. The temperature control elements may include but are not limited to resistive heating elements, thermo-electric heaters/coolers and/or any other type of temperature control elements to control the temperature of the substrate holder 225 that will be apparent to those skilled in the relevant art(s) without departing from the scope of the present disclosure.

The substrate holder 225 may include a clamping system (not shown) to improve thermal transfer between the substrate 220 and the substrate holder 225. The clamping system may include a mechanical clamping system or an electrical clamping system such as an ESC system. The clamping system may affix the substrate 220 to an upper surface of the substrate holder 225. The substrate holder 225 may further include a substrate backside gas delivery system to introduce gas to the back-side of the substrate 220 in order to improve the gas-gap thermal conductance between the substrate 220 and the substrate holder 225. The substrate backside gas system may include a two-zone gas distribution system so that a helium pressure gap may be independently varied between the center and the edge of the substrate 220. The substrate holder 225 may be surrounded by a baffle member 221 that extends beyond a peripheral edge of the substrate holder 225. The baffle member 221 may serve to homogenously distribute the pumping speed delivered by the vacuum pumping system 230 to the electron beam excited plasma region 240. The baffle member 221 may include a dielectric material, such as quartz and/or alumina. The baffle member 221 may provide a high RF impedance path to ground for the electron beam excited plasma 250.

The processing system 200 also includes a controller 292. The controller 292 includes a microprocessor, memory, and a digital input/output port capable of generating control signals sufficient to communicate and activate inputs to processing system 200 as well as monitor outputs from the processing system 200. The controller 292 may be coupled to the plasma generation system 265 to exchange information with the plasma generation system 265. The controller 292 may also be coupled to the first gas injection system 255, the power source 275, the electrode bias system 280, the second gas injection system 260, the DC voltage source 286, the substrate holder 225, and the vacuum pumping system 230. In an embodiment, a program stored in the memory may activate the inputs of the above components of the processing system 200 based on a process recipe to treat the substrate 220.

The controller 292 may be a general purpose computer system to perform a portion or all of the microprocessor based processing steps in response to a processor executing one or more sequences of one or more instructions contained in the memory. Such instructions may be read into the controller memory from another computer readable medium, such as a hard disk or a removable media drive. One or more processors in a multi-processing arrangement may also be employed as the controller processor executes the sequences of instructions contained in main memory. Hard-wired circuitry may also be used in place of or in combination with software instructions. Thus, embodiments are not limited to any specific combination of hardware circuitry and software.

The controller 292 includes at least one computer readable medium or memory, such as the controller memory, for holding instructions programmed according to the teachings of the invention and for containing data structures, tables, records, and/or any other data that may be necessary to process the substrate 220. The term “computer readable medium” as used herein refers to any medium that participates in providing instructions to the processor of the controller 292 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller 292 for execution. For example, the instructions may initially be carried on a magnetic disk of a remote computer. The remote computer can load the instructions for implementing all or a portion of the present invention remotely to a dynamic memory and send the instructions over a network to the controller 292.

Stored on any one or on a combination of computer readable media, the invention includes software for controlling the controller 292 for driving a device or devices for implementing the invention, and/or for enabling the controller to interact with a human user. Such software may include, but is not limited to, device drivers, operating systems, development tools, and applications software. Such computer readable media further includes the computer program product of the invention for performing all or a portion of the processing performed in treating the substrate 220. The computer code devices may be any interpretable or executable code mechanism, including but not limited to, scripts, interpretable programs, dynamic link libraries (DLLs), Java classes, and complete executable programs. Moreover, parts of the processing may be distributed for better performance, reliability, and/or cost.

The controller 292 may be locally located relative to the processing system 200 or it may be remotely located relative to the processing system 200 via a network. Thus, the controller 292 may exchange data with the processing system 200 using at least one of a direct connection, an intranet, or the Internet. The controller 292 may be coupled to an intranet at a customer site or coupled to an intranet at a vendor site. Another computer may access the controller 292 to exchange data via at least one of a direct connection or a network connection.

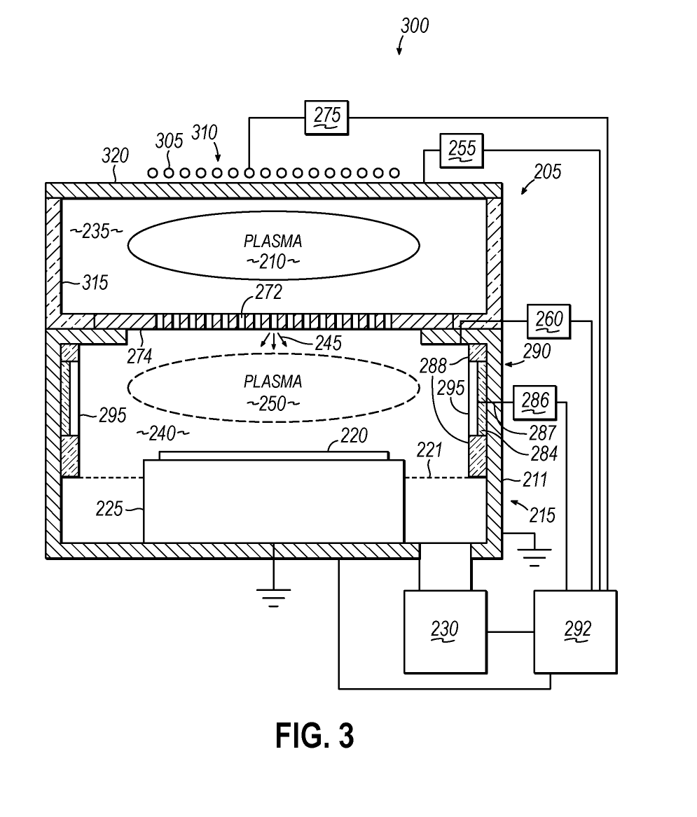

Referring to FIG. 3, in which like reference numerals are used to refer to like parts, a processing system 300 for neutral beam treatment of a substrate is shown. The processing system 300 shares many similar features with the processing systems 100 and 200; therefore, only the differences between the processing system 300 and the processing systems 100 and 200 are to be discussed in further detail. Rather than having the inductive coils located on either side of the of the plasma generation chamber 205, the inductive coil 305 is included in a plasma generation system 310 located above the plasma generation chamber 205. The inductive coil 205 may be a planar coil, a spiral coil, a pancake coil and/or any other inductive coil that will be apparent to those skilled in the relevant art(s) without departing from the scope of the present disclosure. The inductive coil 305 may be in communication with the source plasma 210 from above as in transformer coupled plasma (TCP). RF power is inductively coupled from the inductive coil 305 through a dielectric window 315 to the source plasma 210 in the source plasma region 235. The plasma generation chamber 205 also includes a DC conductive ground electrode 320 having a conductive surface that acts as a boundary in contact with the source plasma 210. The DC conductive ground electrode 320 may be coupled to DC ground.

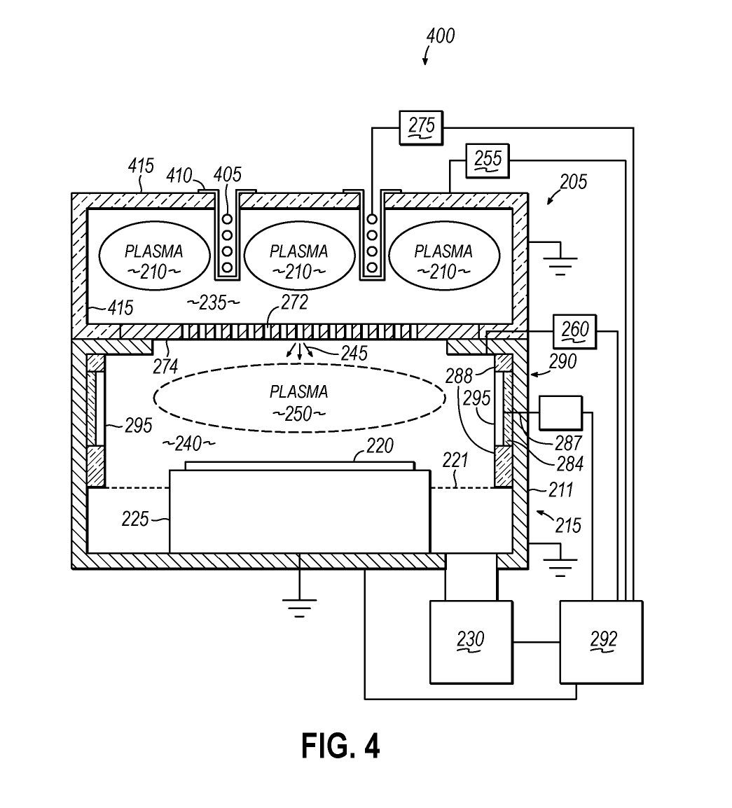

Referring now to FIG. 4, in which like reference numerals are used to refer to like parts, a processing system 400 for neutral beam treatment of a substrate is shown. The processing system 400 shares many similar features with the processing systems 100, 200, and 300; therefore, only the differences between the processing system 400 and the processing systems 100, 200, and 300 are to be discussed in further detail. Rather than having the inductive coils located on the sides or on top of the plasma generation chamber 205, the inductive coil 405 may be located within the source plasma region 235 of the plasma generation chamber 205, where the inductive coil 405 is separated from the source plasma 210 by a cylindrical dielectric window insert 410. The inductive coil 405 may be a cylindrical coil, such as a helical coil, that may be coupled to the power source 275. RF power may be inductively coupled from the inductive coil 405 through the cylindrical dielectric window insert 410 to the source plasma 210 in the source plasma region 235. The plasma generation chamber 205 also includes a DC conductive ground electrode 415 having a conductive surface that acts as a boundary in contact with the source plasma 210. The DC conductive ground electrode 415 may be coupled to DC ground. Since the inductive coil 405 is immersed within the source plasma 210, the DC conductive ground electrode 415 includes a surface area that occupies a substantial fraction of the interior surfaces of the plasma generation chamber 205.

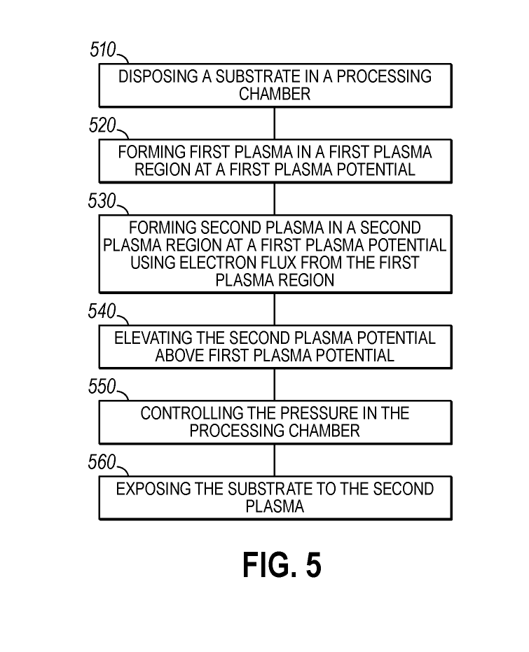

FIG. 5 is a flowchart of exemplary operational steps of a processing system according to an exemplary embodiment of the present disclosure. The present disclosure is not limited to this operational description. Rather, it will be apparent to persons skilled in the relevant art(s) from the teaching herein that other operational control flows are within the scope of the present disclosure. The following discussion describes the steps in FIG. 5.

At step 510, the operational control flow disposes a substrate in a process chamber for treatment of the substrate using plasma.

At step 520, the operational control flow forms source plasma in a source plasma region at source plasma potential. For example, the operational control flow forms source plasma 210 in a source plasma region 235 of a plasma generation chamber 205 at source plasma potential (Vₚ, 1).

At step 530, the operational control flow forms the electron beam excited plasma in an electron beam excited plasma region at an electron beam excited plasma potential using electron flux from the source plasma region. Specifically, an electron beam excited plasma 250, for example, in an electron beam excited plasma region 240 at an electron beam excited plasma potential (Vₚ, 2) may be formed using electron flux 245 from the source plasma region 235. The electron flux 245 may be generated from the source plasma 210 in the source plasma region 235 that passes from the plasma generation chamber 205 through the separation member 272 to the process chamber 215 where the substrate 220 is treated.

At step 540, the operational control flow elevates the electron beam excited plasma potential above the source plasma potential. The source plasma 210 in the source plasma region 235 may be boundary-driven plasma in that the plasma boundary has a substantive influence on the respective plasma potential. Part of the boundary may be in contact with the source plasma 210 that may be coupled to DC ground. The electron beam excited plasma 250 in the electron beam excited plasma region 240 may be also be boundary-driven plasma where part of the boundary in contact with the electron beam excited plasma 250 is coupled to a DC voltage source at +V_{DC}.

At step 550, the operational control flow controls the pressure in the processing chamber. Specifically, a controller 292 controls the pressure in the process chamber 215. Gases entering the process chamber 215 may be pumped by a vacuum pumping system 230 to control the pressure in the process chamber 215.

At step 560, the operational control flow exposes a substrate to the electron beam excited plasma. Specifically, a substrate 220 is exposed to the electron beam excited plasma 250. The exposure of the substrate 220 to the electron beam excited plasma 250 includes exposing the substrate 220 to a neutral beam activated chemical process.

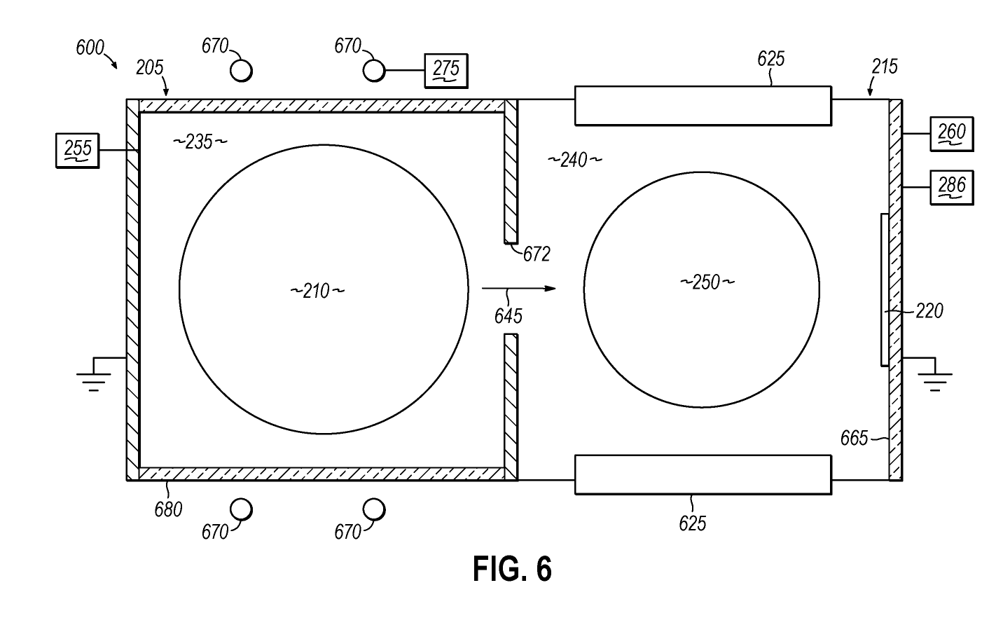

Referring to FIG. 6, in which like reference numerals are used to refer to like parts, a processing system 600 for NEP treatment of a substrate is shown. The processing system 600 shares many similar features with the processing systems 100, 200, 300, and 400; therefore, only the differences between the processing system 600 and the processing systems 100, 200, 300, and 400 are to be discussed in further detail. Rather than having the separation member 274 with one or more openings 272 to allow passage of electron flux 245 from the source plasma region 235 to the electron beam excited plasma region 240, the system is modified to inject electrons into the electron beam 645 to improve the ion efficiency of the electron beam 645. For example, as shown in FIG. 6, the electron beam 645 passes through a dielectric electron injector 672.

As noted above, the first gas injection system 255 is coupled to the plasma generation chamber 205 and introduces the first process gas to the source plasma region 235. In an embodiment, the first process gas may include Ar gas and may be maintained at a pressure ranging from 5 mTorr to 15 mTorr. The first process gas may create the source plasma 210.

The source plasma 210 may then be excited to form the electron beam 645 based on the RF power provided to the source plasma from an inductive coil 670. The inductive coil 670 may be coupled to the power source 275. The power source 275 may include a RF generator that couples RF power at a frequency of 13.56 MHz through an impedance matched network to the inductive coil 670. RF power of 200 W to 300 W may be inductively coupled from the inductive coil 670 through a dielectric tube 680 to the source plasma 210 in the source plasma region 235. The dielectric tube 680 is situated along the sidewalls of the plasma generation chamber 205 and acts as an input port into the plasma generation chamber 205. The dielectric tube 680 may be mated with the inductive coil 670 to provide a hermetic seal for the plasma generation chamber 205 and a portal for transmission of the RF power into the plasma generation chamber 205. The plasma generation chamber 205 may have a large surface that may be coupled to DC ground.

The electron beam 645 may be generated from electric flux that results from the excitation of the source plasma 210 by the RF power inductively coupled to the plasma generation chamber 205 from the inductive coil 670. The electron beam 645 is driven by electric diffusion where the electric flux of the electron beam 645 moves from source plasma region 235 to the electron beam excited plasma region 240 based on the potential difference between the source plasma potential (Vₚ, 1) and the electron beam excited plasma potential (Vₚ, 2).

As the electron beam 645 moves from the source plasma region 235 to the electron beam excited plasma region 240, the electron beam 645 passes through the single dielectric electron injector 672. The single dielectric electron injector 672 injects electrons into the electron beam 645 to balance the positively charged ions included in the electron beam 645 with the injected electrons thus creating a substantially non-ambipolar electron beam. The injection of the electrons into the electron beam 645 improves the ion efficiency of the electron beam 645 so that the quantity of positively charged ions that lose their positive charge may be minimized as the electron beam 645 travels into the electron beam excited plasma region 240.

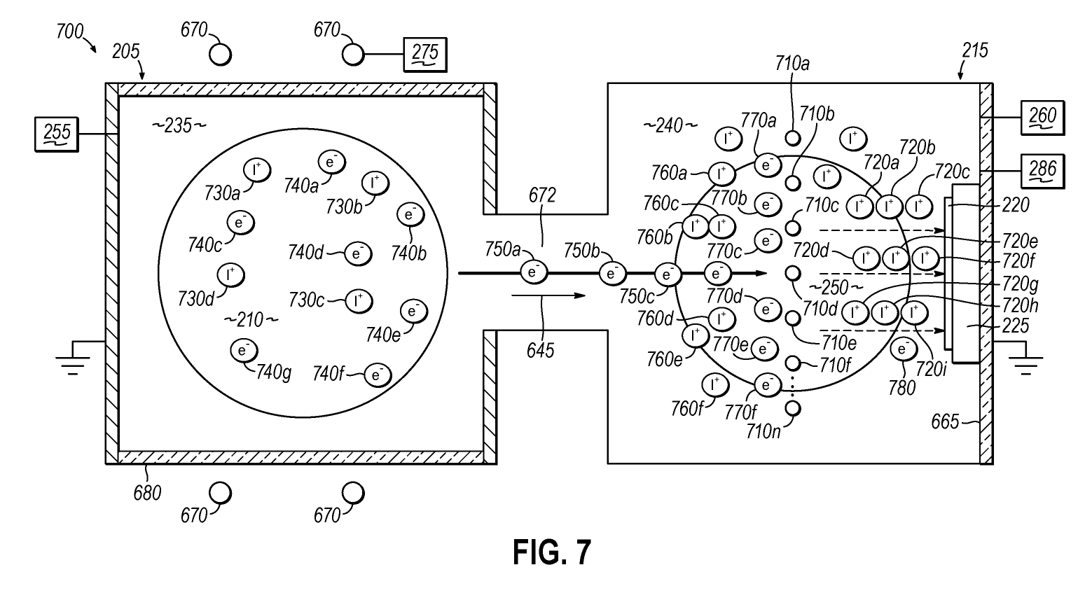

Although the injection of the electrons into the electron beam 645 improves the ion efficiency of the electron beam 645, electrons that reach the substrate 220 may damage the substrate 220. As a result, the quantity of electrons that actually reach the substrate 220 is to be minimized. As the electron beam 645 reaches the substrate 620, a voltage potential surrounding the substrate 220 may be generated that repels the electrons from the substrate 220 and attracts the positively charged ions to the substrate 220. Thus, the quantity of electrons that reach the substrate 220 may be minimized based, at least in part, on the electron beam 645 power, chamber pressure, the magnetic field, or a combination thereof that may be used to form the sheath potential around the substrate 220. The electron beam 645 power may vary between a few milliwatts to several thousand kilowatts depending on the pressure and the magnetic field. The pressure may vary between 0.1 mTorr and 1 Torr depending on the electron beam 645 power and the magnetic field. The magnetic field may be dependent upon the magnitude of the magnetic field, the location and/or shape of the magnets that generate the magnetic field. FIG. 7 illustrates just one embodiment of the location and/or shape of the magnets.

In an embodiment, the single dielectric electron injector 672 separates the source plasma 210 from electron beam excited plasma 250. The single dielectric electron injector 672 may include a single opening with a diameter of 1.0 mm, for example. The single dielectric electron injector 672 limits the electrons included in the source plasma 210 to the electrons with sufficient energy to move through the single opening of the single dielectric electron injector 672 to enter the electron beam excited plasma 250. With each electron that enters the electron beam excited plasma 250 from the single dielectric electron injector 672, a corresponding positively charged ion included in the electron beam excited plasma 250 moves from the process chamber 215 through the single dielectric electron injector 672 and into the plasma generation chamber 205. Thus, the positively charged ions included in the electron beam 645 are balanced with the high energy electrons that passed through the single dielectric electron injector 672 forming a substantially non-ambipolar electron beam that enters the electron beam excited plasma 250.

The second gas injection system 260 may be coupled to the process chamber 215 and may introduce a second process gas to the electron beam excited plasma region 240. In an embodiment, the second process gas may include N₂ at a pressure that ranges from 1 mTorr to 3 mTorr. The second process gas may be injected with the electron beam 645 to create the electron beam excited plasma 250.

After the electron beam 645 enters the process chamber 215, the electron beam 645 may then be accelerated through the excited plasma region 240 to the substrate 220 via a large surface-area positive DC accelerator 625. The accelerator 625 may apply positive DC voltage (+V_{DC}) to the process chamber 215 to propel the positively charged ions included in the electron beam 645 so that the positively charged ions travel through the electron beam excited plasma region 240 and reach the substrate 220. As the electron beam 645 reaches the substrate 220, a sheath potential surrounding the substrate 220 repels the electrons and attracts the positively charged ions so that the positively charged ions that reach the substrate 220 to treat the substrate 220 are maximized while the quantity of electrons that reach the substrate 220 are minimized. The sheath potential of the substrate 220 may be defined as a layer in the electron beam excited plasma 250 that has a density of positively charged ions generated by the floating potential of a dielectric end-plate 665 that may repel electrons included in the electron beam 645 while attracting the positively charged ions included in the electron beam 645. The positive DC voltage (+V_{DC}) applied by the accelerator 625 to accelerate the positively charged ions may range from 80V to 600V.

The accelerator 625 may be coupled to an inside portion of the process chamber 215 and have a diameter substantially similar to the process chamber 215. The accelerator 625 may occupy a large surface area of the process chamber 215 so that the accelerator 625 may adequately accelerate the positively charged ions throughout the process chamber 215. A remaining surface area of the process chamber 215 may include a dielectric end-plate 665 that surrounds the substrate 220. The dielectric end-plate 665 may be the end-plate of the process chamber 215 in that the dielectric end-plate 665 of the process chamber 215 may be located on an opposite end of the process chamber 215 from the dielectric electron injector 672. The dielectric end-plate 665 may be a floating surface, such as quartz for example, with a floating potential and thus creating a sheath potential for the substrate 220. The dielectric end-plate 665 may be floated relative to the positive DC voltage (+V_{DC}) provided by the accelerator 625.

As a result, the positively charged ions included in the electron beam 645 are accelerated through the process chamber 215 until reaching the dielectric end-plate 665. Because the dielectric end-plate 665 is floating, the electrons included the electron beam 645 are repelled and the positively charged ions are attracted by the sheath potential of the dielectric end-plate 665 so only a high quantity of positively charged ions with a minimal quantity of electrons reach the substrate 220 to treat the substrate 220. The accelerator 625 may also maintain the positively charged ions within the well-defined electron beam 645 to achieve desirable IED and micro loading levels in treating the substrate 220.

In an embodiment, the electron beam power of the electron beam 645 may be suppressed by the accelerator voltage to reduce the quantity of electrons that come within the sheath potential of the substrate 220. The damping of the electron beam power by the accelerator voltage limits the amount of electrons that reach the sheath potential and that are eventually repelled by the sheath potential. As a result, the sheath potential may remain stable and not altered. Altering in the sheath potential may result in an increased number of electrons that reach the substrate 220 possibly resulting in a broader IED in treating the substrate 220 and possibly damaging the substrate 220.

Referring to FIG. 7, in which like reference numerals are used to refer to like parts, a processing system 700 for NEP treatment of a substrate is shown. The processing system 700 shares many similar features with the processing systems 100, 200, 300, 400, and 600; therefore, only the differences between the processing system 700 and the processing systems 100, 200, 300, 400, and 600 are to be discussed in further detail. Rather than having the accelerator 625 coupled to the inner diameter of the process chamber 215, the system is modified to include a plurality of metallic rods 710a through 710n where n is an integer greater than or equal to one that generate a magnetic field to repel electrons from reaching the substrate 220 while allowing the positively charged ions to reach the substrate 220. For example, as shown in FIG. 7, the positively charged ions 720a through 720i have passed through the metallic rods 710a through 710n and have reached the substrate 220 to treat the substrate 220.

As noted above, the source plasma 210 may be excited to form the electron beam 645 based on the RF power provided to the source plasma 210 from the inductive coil 670. The source plasma 210 may include a plurality of positively charged ions 730a through 730d and a plurality of electrons 740a through 740g. The RF power provided to the source plasma excites the plurality of electrons 740a through 740g so that a portion of the plurality of electrons 740a through 740g obtain an energy level sufficient to propel the high energized electrons through the dielectric electron injector 672. The high energized electrons propelled through the dielectric electron injector 672 forms the electron beam 645. Conversely, a substantially equivalent amount of positively charged ions (not shown) that are originally included in the electron beam excited plasma 250 are driven through the dielectric electron injector 672 into the source plasma 210 forming the non-ambipolar electron beam.

For example, the plurality of electrons 750a through 750c are electrons that were previously included in the source plasma 210 but obtained energy levels sufficient to propel the electrons 750a through 750c through the dielectric electron injector 672 forming the electron beam 645. The injection of the electrons 750a through 750c into the electron beam 645 improves the ion efficiency of the electron beam 645 so that the quantity of positively charged ions that lose their positive energy may be minimized as the electron beam 645 travels through the electron beam excited plasma region 240.

As the electron beam 645 enters the process chamber 215, the quantity of positively charged ions are substantially equivalent to the quantity of electrons included in the electron beam 645 so that the electron beam 645 remains non-ambipolar. For example, the quantity of positively charged ions included in the plurality of positively charged ions 760a through 760f located in the plasma chamber 215 are substantially equivalent to the quantity of electrons included in the plurality of electrons 770a through 770f. As a result, the non-ambipolar characteristics of the electron beam 645 are maintained as the electron beam 645 moves through the process chamber 215.

As noted above, the electron beam 645 includes a substantially equivalent quantity of electrons and positively charged ions so that the positively charged ions included in the electron beam do not lose their positive charge before reaching the substrate 220 and thus limiting the amount of positively charged ions that are available to treat the substrate 220. However, the quantity of electrons that reach the substrate 220 is to be minimized. Electrons that reach the substrate hinder the treatment of the substrate 220 and may also damage the substrate 220. As a result, as the electron beam 645 reaches the substrate 220, the electrons included in the electron beam 645 are repelled from the substrate 220 while the positively charged ions included in the electron beam 645 are accelerated towards the substrate 220.

The substrate 220 is positioned on the substrate holder 225. The substrate holder 225 is at a floating potential. A plurality of magnetic rods 710a through 710n may be located in between the dielectric electron injector 672 and the substrate 220. The plurality of magnetic rods 710a through 710n form a magnetic field that capture the electrons included in the electron beam 645 forming a voltage potential between magnetic rods 710a through 710n and the substrate holder 225. The potential of the substrate holder 225 may be significantly higher than the potential of the magnetic rods 710a through 710n creating an electric field so that the positively charged ions are accelerated towards the substrate 220. As a result, a high quantity of positively charged ions reach the substrate 220 to treat the substrate 220 while a minimal quantity of electrons also reach the substrate 220 to prevent damage to the substrate 220.

For example, electrons 770a through 770f are captured by the magnetic rods 710a through 710n and generate significant voltage potential between the magnetic rods 710a through 710n and the substrate holder 225. The potential of the substrate holder 225 is significantly higher than the potential of the magnetic rods 710a through 710n creating an electric field. As a result, a plurality of positively charged ions 720a through 720i are propelled through the magnetic rods 710a through 710n to the substrate 220 to treat the substrate 220 while only a single electron 780 passes through the magnetic rods 710a through 710n to reach the substrate 220. The remaining electrons 770a through 770f that are captured fail to pass through the magnetic rods 710a and 710n so that substrate 220 remains protected from such electrons.

In an embodiment, the power of the injected electrons may be dampened by the magnetic rods 710a through 710n before reaching the substrate 220. For example, the electrons 770a through 770f located in the process chamber 215 may have each of their power levels dampened from a first power level to a second power level by the magnetic rods 710a through 710n. The magnetic rods 710a through 710n may dampen the power levels of each electron 770a through 770f based on the magnetic field generated by the magnetic rods 710a through 710n.

The strength of the electric field generated by the difference in the potential of the magnetic rods 710a through 710n and the substrate holder 225 may be based on the dampened power levels of each electron 770a through 770f. The greater amount that the power level of each electron 770a through 770f is dampened and thus lowering the power level of each electron 770a through 770f, the greater the electric field generated from the difference in the potential of the magnetic rods 710a through 710n and the substrate holder 225. The greater the electric field may result in more efficient transport of the positively charged ions 720a through 720i to the substrate 220. As a result, the quantity of positively charged ions 720a through 720i that reach the substrate 220 may be significantly decreased if the power level of each electron 770a through 770f cannot be sufficiently dampened by the magnetic rods 710a through 710n.

In an embodiment, the sheath voltage associated with the sheath potential increases linearly with an accelerator voltage over a first range of accelerator voltages. The accelerator voltage provided by an accelerator (not shown) is substantially similar to the accelerator 625 discussed in FIG. 6. The sheath voltage may be substantially similar to the accelerator voltage when the accelerator voltage is adjusted within a first range of accelerator voltages. The sheath voltage may also remain constant as the accelerator voltage is varied over a second range of accelerator voltages so that the sheath voltage is substantially dissimilar from the accelerator voltage.

For example, the sheath voltage increases linearly with the accelerator voltage when the accelerator voltage is in the range of 0V to 250V so that the sheath voltage is substantially similar to the accelerator voltage. Then, the sheath voltage saturates quickly after the accelerator voltage exceeds 250V and remains constant as the accelerator voltage is adjusted above 250V so that the sheath voltage is substantially dissimilar from the accelerator voltage. As a result, the sheath voltage may be controlled without an external bias by adjusting the accelerator voltage. In being able to control the sheath voltage with the accelerator voltage, the quantity of positively charged ions that reach the substrate 220 relative to the quantity of electrons that also reach the substrate 220 may also be controlled with the accelerator voltage.

The magnitude of the magnetic field generated by magnetic rods 710a through 710n may impact the transition between the first range of accelerator voltages and the second range of accelerator voltages. As noted above, the sheath voltage may increase linearly with the accelerator voltage over a first range of voltages and then drop to a constant voltage when the accelerator voltage is varied over a second range of voltages. The decrease in the sheath voltage may occur at a slower rate when the accelerator voltage is adjusted from the first range of voltages into the second range of voltages when the magnetic field generated by the magnetic rods 710a through 710n is increased.

In an embodiment, one or more electromagnets may be coupled to the magnetic rods 710a through 710n to generate the magnetic field that captures the electrons included in the electron beam 645. The magnetic rods 710a through 710n may also include a barrier material that may minimize diffusion of metal ions into the process chamber 215. The barrier material may include but is not limited to quartz, ceramic, silicon nitride, and/or any other barrier material that prevents diffusion of metal ions that will be apparent to those skilled in the relevant art(s) without departing from the scope of the present disclosure.

The magnetic rods 710a through 710n may be aligned so that each of the magnetic rods 710a through 710n is substantially parallel to the substrate holder 225. The magnetic rods 710a through 710n may be aligned so that a first magnetic rod 710a may be coupled to a first wall of the process chamber 215 and a second magnetic rod 710n may be coupled to a second wall of the process chamber 215 that is opposite the first wall. Each of the other magnetic rods 710a through 710n may be dispersed in between the first magnetic rod 710a and the second magnetic rod 710n while being substantially parallel to the substrate holder 225. Each of the magnetic rods 710a through 710n may be electrically coupled to each other. Each magnetic rod 710a through 710n may be magnetically coupled to at least each adjacent magnetic rod 710a through 710n.

It is to be appreciated that the Detailed Description section, and not the Abstract section, is intended to be used to interpret the claims. The Abstract section can set forth one or more, but not all exemplary embodiments, of the present disclosure, and thus, is not intended to limit the present disclosure and the appended claims in any way.

While the present invention has been illustrated by the description of one or more embodiments thereof, and while the embodiments have been described in considerable detail, they are not intended to restrict or in any way limit the scope of the appended claims to such detail. Additional advantages and modifications will readily appear to those skilled in art. The invention in its broader aspects is therefore not limited to the specific details, representative apparatus and method and illustrative examples shown and described. Accordingly, departures may be made from such details without departing from the scope of the general inventive concept.

What is claimed is:

1. A processing system for non-ambipolar electron plasma (NEP) treatment of a substrate, comprising:
a plasma source chamber configured to excite a source plasma to generate an electron beam;
a process chamber configured to house a substrate for exposure of the substrate to the electron beam;
an electron injector configured to inject electrons from the source plasma into the electron beam as the electron beam enters the process chamber, wherein the electron beam includes a substantially equal number of electrons and positively charged ions in the process chamber; and
a magnetic field generator configured to generate a magnetic field in the process chamber to capture the electrons included in the electron beam to generate a voltage potential between the magnetic field generator and the substrate, wherein the voltage potential accelerates the positively charged ions to the substrate and minimizes the electrons that reach the substrate.

2. The processing system of claim 1, wherein the magnetic field generator comprises:
a plurality of metallic rods arranged between the electron injector and the substrate; and
at least one electromagnet coupled to at least one of the metallic rods.

3. The processing system of claim 2, wherein each of the metallic rods is positioned substantially parallel to the substrate.

4. The processing system of claim 2, wherein each of the metallic rods is covered with a barrier material that is configured to minimize diffusion of metal ions included in each of the metallic rods into the process chamber.

5. The processing system of claim 4, wherein the barrier material is selected from a group consisting of quartz, ceramic, and silicon nitride.

6. The processing system of claim 2, wherein the plurality of metallic rods extend from a first chamber wall included in the process chamber to a second chamber wall included in the process chamber covering a width of the process chamber that is substantially parallel to the substrate.

7. The processing system of claim 6, wherein a first metallic rod of the plurality of metallic rods coupled to the first chamber wall is substantially aligned with a second metallic rod of the plurality of metallic rods coupled to the second chamber wall with each remaining metallic rod of the plurality of metallic rods substantially aligned between the first metallic rod and the second metallic rod so that each of the plurality of metallic rods is substantially parallel to the substrate.

8. The processing system of claim 2, wherein each of the metallic rods is electrically coupled to each of the other metallic rods.

9. The processing system of claim 2, wherein each of the metallic rods is magnetically coupled to at least each adjacent one of the metallic rods.

10. The processing system of claim 1, wherein the magnetic field generator is further configured to dampen a power level of the electrons included in the electron beam to increase the voltage potential between the magnetic field generator and the substrate.

11. A processing system for non-ambipolar electron plasma (NEP) treatment of a substrate, comprising:
a plasma source chamber configured to excite a source plasma to generate an electron beam;
a process chamber configured to house a substrate for exposure of the substrate to the electron beam;
an electron injector configured to inject electrons from the source plasma into the electron beam as the electron beam enters the process chamber, wherein the electron beam includes a substantially equal number of electrons and positively charged ions in the process chamber; and
a positively charged ion accelerator configured to generate a direct current (DC) voltage to the process chamber to accelerate the positively charged ions to the substrate and minimize the electrons that reach the substrate.

12. The processing system of claim 11, wherein the positively charged ion accelerator is further configured to generate from the DC voltage a sheath potential between the positively charged ion accelerator and the substrate that accelerates the positively charged ions to the substrate and repels the electrons that reach the substrate.

13. The processing system of claim 12, wherein the positively charged ion accelerator is further configured to generate a magnetic field in the process chamber to capture the electrons included in the electron beam to generate the sheath potential.

14. The processing system of claim 12, wherein the positively charged ion accelerator is further configured to dampen a power level of the electrons included in the electron beam as the electrons enter the process chamber so that the sheath potential is not weakened by the electrons included in the electron beam.

15. The processing system of claim 14, wherein the positively charged ion accelerator dampens the power level of the electrons included in the electron beam by generating the magnetic field in the process chamber.

16. A processing system for non-ambipolar electron plasma (NEP) treatment of a substrate, comprising:
a plasma source chamber configured to excite a source plasma to generate an electron beam;
a process chamber configured to house a substrate for exposure of the substrate to the electron beam;
an electron injector configured to inject electrons from the source plasma into the electron beam as the electron beam enters the process chamber, wherein the electron beam includes a substantially equal number of electrons and positively charged ions in the process chamber;
a magnetic field generator configured to capture the electrons included in the electron beam to generate a sheath potential between the substrate and the magnetic field generator from a magnetic field generated by the magnetic field generator, wherein the sheath potential attracts the positively charged ions to the substrate and minimizes the electrons that reach the substrate; and
a positively charged ion accelerator configured to generate an accelerator voltage to the process chamber to accelerate the positively charged ions to the substrate.

17. The processing system of claim 16, wherein a sheath voltage of the sheath potential varies in a substantially linear fashion with the accelerator voltage as the accelerator voltage is adjusted over a first range of accelerator voltages and the sheath voltage is substantially constant as the accelerator voltage is adjusted over a second range of accelerator voltages.

18. The processing system of claim 17, wherein the sheath voltage decreases at a sheath voltage rate when the accelerator voltage is adjusted from the first range of accelerator voltages into the second range of accelerator voltages.

19. The processing system of claim 18, wherein an increase in a magnetic field level of the magnetic field generated by the magnetic field generator results in a decrease in the sheath voltage rate when the accelerator voltage is adjusted from the first range of accelerator voltages into the second range of accelerator voltages.

20. The processing system of claim 17, wherein the sheath potential between the substrate and the magnetic field generator is controlled by adjusting the accelerator voltage.
